(19) United States
(12) Patent Application Publication
(10) Pub. No.: US 2009/0289350 A1
(43) Pub. Date: Nov. 26, 2009

(54) SEMICONDUCTOR PACKAGE, SUBSTRATE, ELECTRONIC DEVICE USING SUCH SEMICONDUCTOR PACKAGE OR SUBSTRATE, AND METHOD FOR CORRECTING WARPING OF SEMICONDUCTOR PACKAGE

(75) Inventor: Shinji Watanabe, Minato-ku (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION, Minato-ku (JP)

(21) Appl. No.: 12/066,795

(22) PCT Filed: Jul. 5, 2006
(86) PCT No.: PCT/JP2006/313391

§ 371 Date: Mar. 13, 2008

(30) Foreign Application Priority Data
Sep. 29, 2005 (JP) 2005-284193

(51) Int. Cl. H01L 23/12; H05K 1/03; H01L 21/26

(52) U.S. Cl. 257/701; 174/255; 438/795; 257/E23.003; 257/E21.328

(57) ABSTRACT

Disclosed is a semiconductor package wherein a semiconductor chip is mounted on one surface of a substrate. In this semiconductor package, an inflection point forming portion made of a material having a higher coefficient of thermal expansion than the substrate is formed in a part of the substrate surface on which the semiconductor chip is mounted.

### TECHNICAL FIELD

The present invention relates to a semiconductor package, and a substrate used in this semiconductor package. Particularly, the present invention relates to a semiconductor package which has a semiconductor chip mounted on a substrate by a flip-chip method. Also, the present invention relates to an electronic device which uses the substrate or semiconductor package. Further, the present invention relates to a method for correcting warping of such a semiconductor package.

### BACKGROUND ART

With increasing reductions in size and thickness of portable terminals, semiconductor packages are required to be reduced in size and thickness. To meet such requirements, there is an increased need for semiconductor packages which apply a flip-chip connection technology. The flip-chip connection technology, herein referred to, is a technology which involves providing terminals on a circuit surface of a semiconductor chip, and directly connecting these terminals to pads on a substrate using solder balls.

Further, there is an increased requirement for mounting a semiconductor package in a lower profile. To this end, a reduction in thickness is desired for a semiconductor chip and a substrate on which it is mounted. On the other hand, the number of external terminals tends to increase in step with improvements in performance of electronic devices which employ them. As a result, semiconductor packages tend to increase in size. It is essential to further reduce the pitch at which external terminals are arranged in order to restrain an increase in the size of semiconductor packages. To this end, it is necessary to reduce the diameter of solder balls which are used for making connections with the external terminals.

The warping of semiconductor packages which accompanies such a reduction in thickness of semiconductor packages and substrates has become problematic. The warping is caused by a variety of thermal loads which occur in manufacturing processes due to different coefficients of thermal expansion of respective elements which make up a semiconductor package. The thermal loads occur, for example, when a semiconductor chip is connected to a substrate by a flip-chip method, or when the aforementioned solder balls are reflowed (i.e., solder is reflowed) when another substrate is connected to the semiconductor package. Here, the mounted semiconductor chip exhibits a coefficient of thermal expansion of approximately 3×10⁻⁶/K, while glass cloth which forms part of the substrate has a coefficient of thermal expansion of approximately 15×10⁻⁶/K.

FIG. 1 shows an example of such a conventional semiconductor package in plan view. Further, FIGS. 2A-2C show the semiconductor package, when it is warped, in cross-sectional view. In this structure, semiconductor chip 1 is connected to substrate 2 by a flip-chip method. External terminals 3 are arranged on the same substrate surface as semiconductor chip 1 in a lattice form so as to surround semiconductor chip 1. Semiconductor chip 1 and substrate 2 are electrically connected through bumps. Further, underfill resin 4 is filled in a gap between semiconductor chip 1 and substrate 2. External terminals 3 are formed of semiconductor balls. By connecting this semiconductor package to another substrate using the solder balls, a new semiconductor package is formed, including this semiconductor package. FIG. 2A is a schematic cross-sectional view taken along A-A′ in FIG. 1, showing the state of the package at room temperature after connecting semiconductor chip 1 and substrate 2, and after underfill resin 4 has been filled and cured in a semiconductor package manufacturing step shown in FIG. 1. Underfill resin 4 is generally cured at temperatures approximately ranging from 180 to 250° C., so that substrate 2 is actually heated to a temperature of approximately 150-220° C. during this curing step. At this temperature, substrate 2 which exhibits a larger coefficient of thermal expansion, i.e., approximately 15×10⁻⁶/K, is connected, while expanded, to semiconductor chip 1 which exhibits the coefficient of thermal expansion of approximately 3×10⁻⁶/K. Accordingly, at the time they return to room temperature after being connected, a contraction of substrate 2 causes warping in a direction in which the surface, on which semiconductor chip 1 is mounted, is convex (see FIG. 2A). On the other hand, when another substrate is connected to this semiconductor package, external terminals 3 are formed on substrate 2, followed by a solder reflow step. The solder reflow is performed at temperatures higher than the melting point of solder (for example, 225° C.), for example in a range of 240-260° C. Substrate 2 again expands during this solder reflow. FIGS. 2B, 2C show the states of the package in a reflow temperature range, where FIG. 2B is a schematic cross-sectional view taken along A-A′ in FIG. 1, and FIG. 2C is a schematic cross-sectional view taken along B-B′ in FIG. 1. Since this reflow temperature is higher than the curing temperature of the aforementioned underfill resin 4, substrate 2 warps in the direction opposite to the state shown in FIG. 2A. As can be seen from the cross-sectional view taken along A-A′ shown in FIG. 2B, the distance between the other substrate and the solder balls on external terminals 3 is larger at a position closer to the center of the package. Also, as can be seen from the cross-sectional view taken along B-B′ shown in FIG. 2C, the distance between the other substrate and the solder balls of external terminals 3 is larger at a position closer to the center of the sides even in the periphery of the package. If the interstice between the other substrate and the solder balls cannot be filled with cream solder which is supplied to the solder balls and other substrate and even if which is melted therein, defective connections arise. As such, the center of the side is particularly susceptible to a defective connection.

FIGS. 1, 2 show an example in which semiconductor chip 1 and external terminals 3 are disposed on the same surface of substrate 2. Another example is shown for a semiconductor package which has semiconductor chip 1 and external terminals 3 disposed on different surfaces. FIG. 3 is a plan view of the same, and FIGS. 4A-4C are cross-sectional views of the same. FIG. 4A is a schematic cross-sectional view taken along A-A′ in FIG. 3, showing the state of the package at room temperature after connecting semiconductor chip 1 and substrate 2, and after underfill resin 4 has been filled and cured in a semiconductor package manufacturing process shown in FIG. 3. In this state, warping occurs in a direction in which the surface on which semiconductor chip 1 is mounted is concave (see FIG. 4A). On the other hand, during solder reflow, expansion of substrate 2 causes warping in the direction opposite to the state shown in FIG. 4A (see FIG. 4B). In this event, as can be seen from the cross-sectional view taken along A-A′ shown in FIG. 4B, the distance between the other substrate and the solder balls of external terminals 3 is larger at a position closer to the periphery of the package. Also, as can be seen from the cross-sectional view taken along B-B′ shown in FIG. 4C, the distance between the other substrate and the solder balls of external terminals 3 is larger at a position closer to the ends of sides in the outer periphery of the package as well. In this way, though the warping state is different from the structure shown in FIGS. 1 and 2, defective connections arise if the interstice between the other substrate and the solder balls is not filled with cream solder which is supplied to the solder balls and other substrate and even if which is melted.

Also, in the field of portable devices, among others, thin semiconductor packages have been provided by reducing the thickness of semiconductor chips, substrates, and the like. Since the rigidity of such thin semiconductor packages is degraded, warping of the semiconductor packages is prominent. Further, an increasing reduction in the diameter of solder balls used for connection results in an ever smaller allowance for warping. Also, the warping of packages is promoted in part by the inevitable application of unleaded solder which exhibits a higher melting point and thus requires higher temperature for its reflow, due to RoHS (Restrictions on the use of certain Hazardous Substances) that is intended to reduce environment loads in recent years. Thus, defective connections due to warping have become increasingly prominent.

The warping is restrained by high rigidities, if exhibited by semiconductor chip 1 and substrate 2 themselves, so that the warping is reduced if the rigidities are at a certain level or higher. However, particularly when semiconductor chip 1 has a thickness of 0.3 mm or less, or when substrate 2 has a thickness of 0.8 mm or less, prominently defective connections arise due to the warping of the semiconductor package during a solder reflow.

To restrain this warping, an action is taken to ensure sufficient rigidity, for example, by molding an entire semiconductor package with a resin. Generally, a structure shown in FIG. 5, as described in JP-2002-170901-A, is applied to a conventional flip-chip type semiconductor package for which this action is taken. In this structure, semiconductor chip 1 is connected to substrate 2 by a flip-chip method. Semiconductor chip 1 and substrate 2 are electrically connected through bumps. Further, underfill resin 4 is filled in an interstice between semiconductor chip 1 and substrate 2 for reinforcement of connections. This structure is connected to another substrate by external terminals 3. Further, mold resin 8 is formed to cover entire substrate 2 on which semiconductor chip 1 is mounted. Then, solder balls are arranged in a lattice form as external terminals 3 on the surface of substrate 2 opposite to the surface on which mold resin 8 is formed. In the following, an area in which external terminals 3 are formed is referred to as the connection area. This semiconductor package is electrically connected to another substrate through these solder balls. As mentioned above, semiconductor chip 1 differs from substrate 2 in the coefficient of thermal expansion. In this structure, warping is restrained by having the semiconductor package made of a highly rigid mold resin. Accordingly, the material for mold resin 8 is required to have a coefficient of thermal expansion close to that of the materials for semiconductor chip 1 and substrate 2.

Also, a semiconductor package provided with a metal reinforcing plate has also been proposed in order to further reduce the warping. As an example thereof, FIG. 6 shows a structure described in the specification of Japanese Patent No. 3395164. In this figure, semiconductor device 10 comprises substrate 12, semiconductor chip 14, bumps 16, structure 18, adhesive 20, underfill resin 22, external terminal 24, cavity 26, and interstice 28. Such a structure is widely employed in highly functional and high performance semiconductor packages intended for large computers, having very large semiconductor package sizes. In this structure, structure 18 is attached as a reinforcing plate. Generally, a highly rigid metal material is used for this structure 18. The method for reinforcement only with a mold resin, as shown in FIG. 5, experiences difficulties in completely eliminating warping of packages during solder reflow due to an insufficient rigidity of the resin material. On the contrary, in the structure provided with the reinforcing plate, since substrate 12 is firmly supported by a more rigid metal frame, the warping is more effectively prevented although the cost is increased.

However, in the structure provided with the reinforcing plate, it is difficult to reduce the size and thickness of a semiconductor package. As a result, this structure encounters difficulties when applied to portable devices in which a reduction in thickness and size is required. Further, in recent years, as semiconductor packages that are suitable for portable devices, System in Package (SiP) which contains a plurality of semiconductor packages in a single larger semiconductor package, has enjoyed a brisk business as high performance packages. In the foregoing structure provided with a reinforcement such as a mold resin, a reinforcing plate or the like, an area in which the reinforcement exists is a dead area (area which cannot be used to mount parts). In other words, the area for mounting other semiconductor packages or electronic parts on a semiconductor package has shrunk. This results in a problem in which there is a limited number of semiconductor packages which can be contained, or a problem in which the size of the semiconductor packages will increase if an attempt is made to contain a large number of semiconductor packages, leading to difficulties of highly dense mounting. Consequently, it is difficult to realize small, thin, highly functional semiconductor packages which can be applied to portable devices.

### DISCLOSURE OF THE INVENTION

The present invention has been made in view of the problems of the related art described above. It is an object of the invention to reduce defective solder connections and enhance connection reliability by preventing a semiconductor package from warping during solder reflow. Also, it is another object of the invention to provide a semiconductor package which is suitable for a reduction in size and thickness and an increase in density by reducing a dead area when achieving the aforesaid object.

A semiconductor package to achieve the above object comprises a substrate, a semiconductor chip mounted on one surface of the substrate, and an inflection point forming portion for forming an inflection point. This inflection point forming portion is formed in a part of the surface of the substrate on which the semiconductor chip is mounted, and may be made of a material having a larger coefficient of thermal expansion than the substrate.

Alternatively, the inflection point forming portion may be formed in a part of a surface of the substrate opposite to the surface on which the semiconductor chip is mounted, and may be made of a material having a smaller coefficient of thermal expansion than the substrate.

Such an inflection point forming portion is preferably formed around the outer periphery of the semiconductor chip on the substrate. Also, the inflection point forming portion may include a break in a part thereof to facilitate the manufacturing of the package.

Also, when the semiconductor package as described above is connected to another substrate by using solder, the material of the inflection point forming portion preferably exhibits a modulus of elasticity that is higher than a modulus of elasticity of the substrate at the melting point of the solder.

Further, a resin material or an inorganic material can be applied as the material of the inflection point forming portion.

Also, the present invention can provide a substrate comprising an inflection point forming portion as described above, an electronic device comprising this substrate, and an electronic device comprising a semiconductor package as described above.

The present invention also encompasses a method for correcting warping in a semiconductor package which has a semiconductor chip mounted on one surface of a substrate. This method comprises performing a thermal step after forming an inflection point forming portion made of a material that exhibits a larger coefficient of thermal expansion than the substrate in a part of the surface on which the semiconductor chip is mounted on the substrate. Alternatively, the method may comprise performing a thermal step after forming an inflection point forming portion made of a material that exhibits a smaller coefficient of thermal expansion than the substrate in a part of the surface opposite to the surface on which the semiconductor chip is mounted on the substrate.

In the semiconductor package configured as described above, the inflection point forming portion can generate stress in a direction opposite to warping which occurs due to a difference in the coefficient of thermal expansion between the semiconductor chip and the substrate as a thermal load occurs during solder reflow. Thus, inflection points occur when the substrate warps at solder reflow temperatures. In this way, since a connection area, which is particularly required to be horizontal, can be made parallel to another substrate to be connected, defective solder connections are prevented. Further, since the stress in the direction opposite to the warping of the semiconductor package is generated by the inflection point forming portion arranged in a part of the semiconductor package, it is possible to realize a warping reducing function in a minimally occupied area. Consequently, a dead area is reduced, and highly dense mounting is enabled in the package.

As described above, the present invention can realize a small, low-profile semiconductor package which is free from defective connections during solder reflow, highly reliable, and suitable for portable devices.

### BRIEF DESCRIPTION OF THE DRAWINGS

FIG. 1

A plan view of a first example of a conventional semiconductor package.

FIG. 2A

A cross-sectional view of the semiconductor package of FIG. 1 taken along A-A′, which is a state diagram after a flip-chip connection has been made.

FIG. 2B

A cross-sectional view of the semiconductor package of FIG. 1 taken along A-A′, which is a state diagram during a reflow step.

FIG. 2C

A cross-sectional view of the semiconductor package of FIG. 1 taken along B-B′, which is a state diagram during a reflow step.

FIG. 3

A plan view of a second example of a conventional semiconductor package.

FIG. 4A

A cross-sectional view of the semiconductor package of FIG. 3 taken along A-A′, which is a state diagram after a flip-chip connection has been made.

FIG. 4B

A cross-sectional view of the semiconductor package of FIG. 3 taken along A-A′, which is a state diagram during a reflow step.

FIG. 4C

A cross-sectional view of the semiconductor package of FIG. 3 taken along B-B′, which is a state diagram during a reflow step.

FIG. 5

A cross-sectional view of a third example of a conventional semiconductor package.

FIG. 6

A cross-sectional view of a fourth example of a conventional semiconductor package.

FIG. 7

A plan view of a semiconductor package in a first embodiment of the present invention.

FIG. 8A

A cross-sectional view of the semiconductor package of FIG. 7 taken along A-A′, which is a state diagram after a flip-chip connection has been made.

FIG. 8B

A cross-sectional view of the semiconductor package of FIG. 7 taken along A-A′, which is a state diagram during a reflow step.

FIG. 8C

A cross-sectional view of the semiconductor package of FIG. 7 taken along B-B′, which is a state diagram during a reflow step.

FIG. 9

A diagram showing an example of temperature dependence of the modulus of elasticity of a substrate used in the semiconductor package of the present invention.

FIG. 10

A diagram showing an example of temperature dependence of the modulus of elasticity of a material in an inflection point forming portion used in the semiconductor package of the present invention.

FIG. 11

A plan view of a semiconductor package in a second embodiment of the present invention.

FIG. 12A

A cross-sectional view of the semiconductor package of FIG. 11 taken along A-A′, which is a state diagram after a flip-chip connection has been made.

FIG. 12B

A cross-sectional view of the semiconductor package of FIG. 11 taken along A-A′, which is a state diagram during a reflow step.

FIG. 12C

A cross-sectional view of the semiconductor package of FIG. 11 taken along B-B′, which is a state diagram during a reflow step.

FIG. 13

A plan view of a semiconductor package in a third embodiment of the present invention.

FIG. 14

A plan view of a semiconductor package in a fourth embodiment of the present invention.

FIG. 15A

A plan view of a semiconductor package in a fifth embodiment of the present invention.

FIG. 15B

A cross-sectional view taken along A-A′ in FIG. 15A.

FIG. 16A

A plan view of a semiconductor package in a sixth embodiment of the present invention.

FIG. 16B

A cross-sectional view taken along A-A′ in FIG. 16A.

FIG. 17

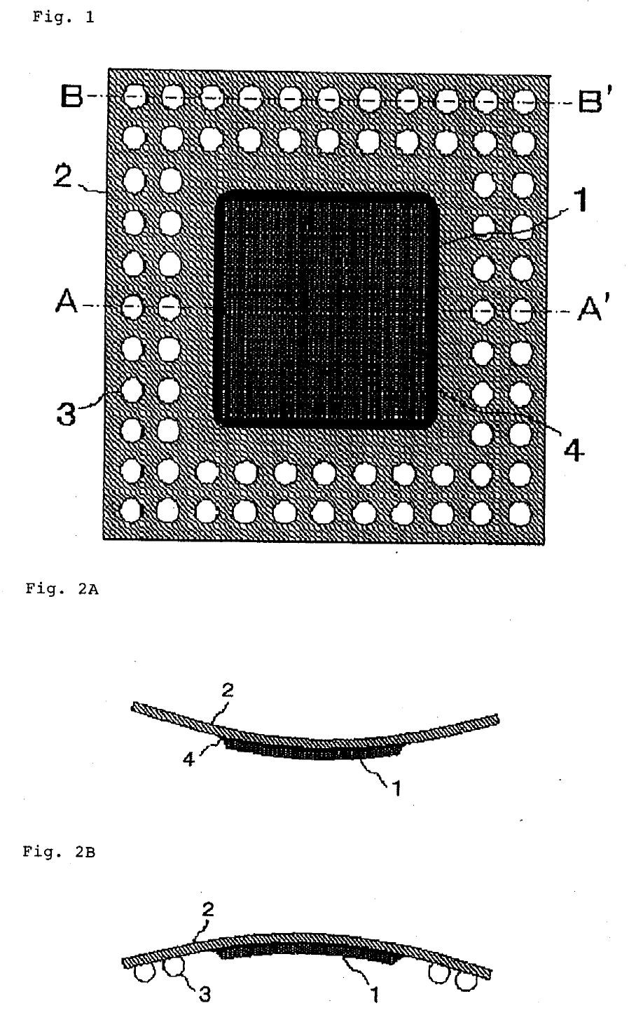

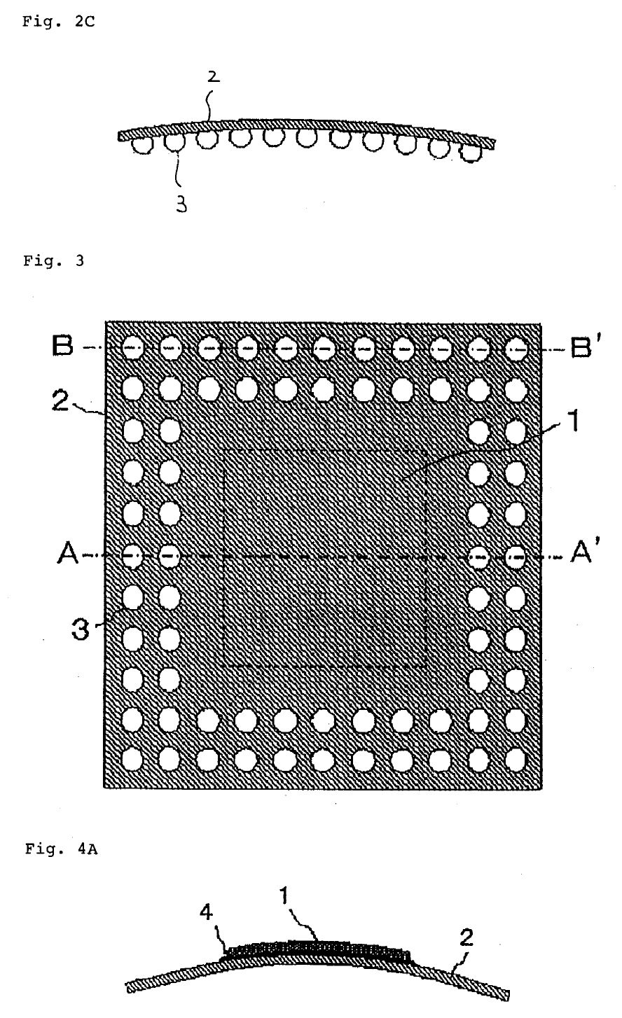

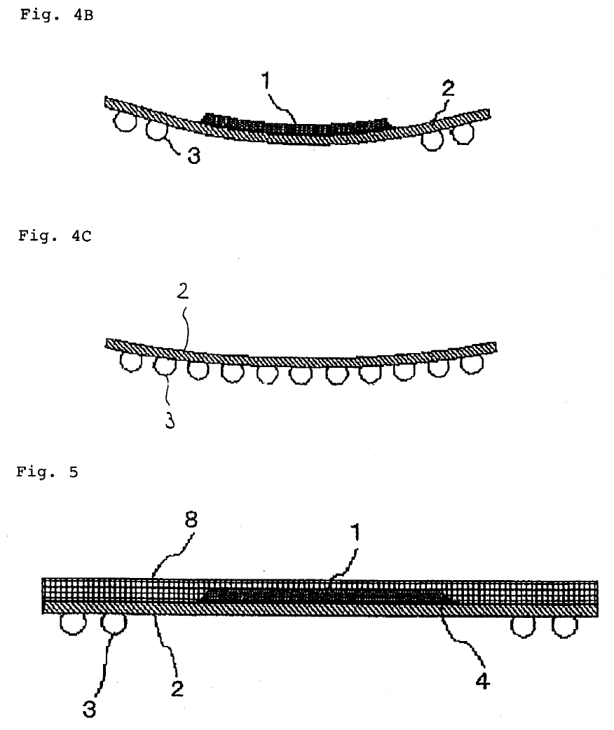

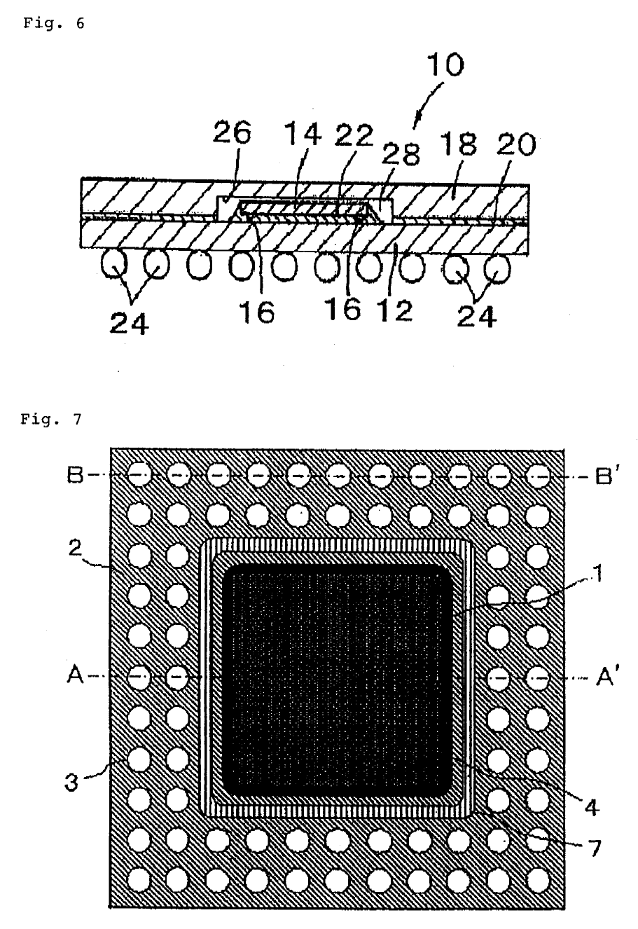

A plan view of a semiconductor package in a seventh embodiment of the present invention.

### BEST MODE FOR CARRYING OUT THE INVENTION

In the following, embodiments of the present invention will be described with reference to the drawings.

A semiconductor package of the present invention has a semiconductor chip mounted on one surface of a substrate, where an inflection point forming portion is formed in a part of the surface on which the semiconductor chip is mounted. This substrate warps due to the difference in the coefficient of thermal expansion between the semiconductor chip and the substrate. The inflection point forming portion is made of a material which is capable of generating warping in the direction opposite to the warping. In this way, since a connection area can be nearly horizontal during solder reflow, defective solder connections can be restrained when this semiconductor package is connected to another substrate. A material for forming the inflection point forming portion used herein can be a material having a larger coefficient of thermal expansion than a material which comprises the substrate. The formation of the inflection point forming portion may be performed before or after the semiconductor chip is mounted. In the former case, the semiconductor package can be manufactured by connecting the semiconductor chip to the substrate previously formed with the inflection point forming portion by a flip-chip method.

FIG. 7 is a plan view of a semiconductor package according to a first embodiment of the present invention. In this figure, semiconductor chip 1 and external terminals 3 are arranged on the same surface of substrate 2. Semiconductor chip 1 is connected to substrate 2 by a flip-chip method. Underfill resin 4 is filled between semiconductor chip 1 and substrate 2. Further, inflection point forming portion 7 is formed in a region between semiconductor chip 1 and external terminals 3 along the outer periphery of semiconductor chip 1 on substrate 2.

Semiconductor chip 1 is a chip made of silicon, which is formed with semiconductor LSIs, for example, logic, memory and the like.

Substrate 2 serves as a substrate which is to be mounted on another part, and is formed, for example, of a very highly rigid material “FR-4” which is based on a glass cloth material. Semiconductor chip 1 and substrate 2 are electrically connected through bumps.

External terminals 3 are connections where there are in between this semiconductor package and another substrate, and are formed of solder balls. A region in which a plurality of external terminals 3 are arranged in a lattice form defines a connection area.

Underfill resin 4 is filled in an interstice between semiconductor chip 1 and substrate 2, and serves to reinforce a connection force therebetween. This resin is, for example, a thermosetting epoxy resin. Underfill resin 4 is formed by filling this material, and then curing it at temperatures of 180-250° C., by way of example.

Inflection point forming portion 7 is made of a material which can cause substrate 2 to warp in a direction opposite to a direction in which semiconductor chip 1 is warped when heat is applied to this semiconductor package (i.e., warping in a direction in which the side formed with inflection point forming portion 7 is formed is convex). This will be described later in greater detail.

This semiconductor package is connected to another package through external terminals 3. This results in the formation of a new semiconductor package which includes this semiconductor package.

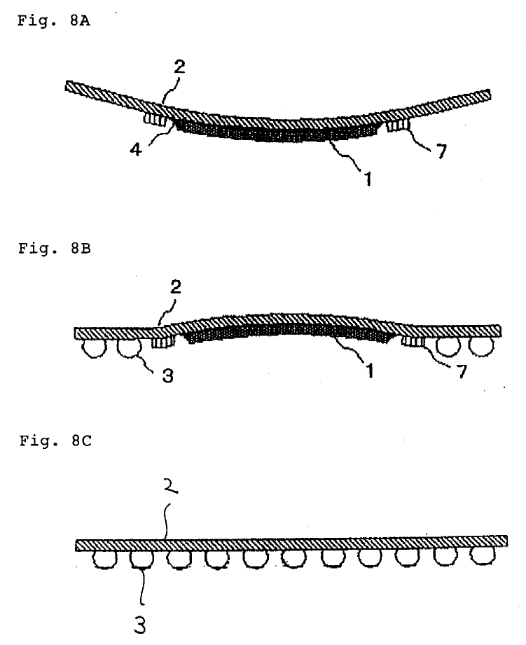

In a method of manufacturing the semiconductor package of this example, after inflection point forming portion 7 is formed, substrate 2 and another substrate are connected using solder balls. In other words, the semiconductor package of this structure is connected to another substrate through solder reflow after it is manufactured through the steps of connecting semiconductor chip 1 and substrate 2, and forming inflection point forming portion 7. In these steps, a description will be given below of how the warping of this semiconductor package changes. FIGS. 8A-8C are diagrams showing situations of the warp in cross-section of the semiconductor package of FIG. 7. Though these figures do not show another substrate which is to be connected to the semiconductor package of this example, it is placed below the semiconductor package in the figure.

Semiconductor chip 1 is connected to substrate 2 by a flip-chip method. For performing the flip-chip connection, there are several methods available, including a pressure welding method, thermo-compression bonding, solder fusion method, ultrasonic compression bonding, and the like. In any method, heat is applied when making the flip-chip connection. For example, in a flip-chip connection by the pressure welding method, underfill resin 4 is generally cured at temperatures approximately ranging from 180 to 250° C., so that substrate 2 is heated to temperature of approximately 150-220° C. during this curing step. At this temperature, substrate 2 which exhibits a larger coefficient of thermal expansion, i.e., approximately 15×10⁻⁶/K, is connected, while expanded, to semiconductor chip 1 which exhibits the coefficient of thermal expansion of approximately 3×10⁻⁶/K at this temperature. Accordingly, at the time they return to a room temperature after the flip-chip connection has been preformed, a contraction of substrate 2 causes warping in a direction in which the surface on which semiconductor chip 1 is mounted is convex (see FIG. 8A). This warping is more prominent because the thickness of the semiconductor chip 1 and substrate 2 is smaller, and because the size of semiconductor chip 1 is larger. On the other hand, the degree of warping near inflection point forming portion 7 depends on a method of forming inflection point forming portion 7. For example, when the material of inflection point forming portion 7 is adhered onto substrate 2 at temperatures near room temperature, or when the material of inflection point forming portion 7 is made of resin which is cured at temperatures near room temperature to form inflection point forming portion 7, this portion can be made substantially flat at the room temperature.

The solder reflow is subsequently performed at temperatures of approximately 240-260° C. because the melting point of unleaded solder, for example, Sn-3.5Ag-0.5Cu, if used, is 225° C. Therefore, substrate 2 again expands during this solder reflow. As a result, substrate 2 warps in the direction opposite to the state of FIG. 8A. FIGS. 8B, 8C show the states of the package in this reflow temperature range, where FIG. 8B is a schematic cross-sectional view taken along A-A′ in FIG. 7, and FIG. 8C is a schematic cross-sectional view taken along B-B′ shown in FIG. 7. Here, since semiconductor chip 1 is formed, along its periphery, with inflection point forming portion 7 which has a larger coefficient of thermal expansion than substrate 2, substrate 2 warps in this portion in a direction opposite to a portion in which semiconductor chip 1 is connected. Specifically, the portion in substrate 2 formed with inflection point forming portion 7 warps in a shape in which the surface formed with inflection point forming portion 7 is formed is convex. In this way, since the warping shape changes at an inflection point where there is near inflection point forming portion 7, substrate 2 outside of inflection point forming portion 7 becomes more horizontal. Consequently, the connection area in which external terminals 3 are formed is substantially horizontal. It is therefore possible to reduce defective connection between this semiconductor package and another substrate.

The occurrence of the warp in the opposite direction in this inflection point forming portion 7, and the amount of warping can be adjusted by the properties of the material of inflection point forming portion 7, and the thickness, width and the like of inflection point forming portion 7.

As a material for inflection point forming portion 7, it is preferable to select a material which exhibits a relatively large coefficient of thermal expansion, and which is required to have at least a higher coefficient of thermal expansion than substrate 2. For example, from the fact that a glass cloth substrate of a material “FR-4” generally used as a material for substrate 2 exhibits a coefficient of thermal expansion of 15×10⁻⁶/K, the material of inflection point forming portion 7 must exhibit a coefficient of thermal expansion larger than this. A specific material which satisfies this is an epoxy resin in resin materials.

Also, for causing substrate 2 to effectively warp in the opposite direction, a sufficiently high rigidity is required to cause substrate 2 to warp in the solder reflow temperature range. For this purpose, the material of inflection point forming portion 7 preferably exhibits modulus of elasticity higher than substrate 2 in the solder reflow temperature range. Since the solder reflow is performed at temperatures higher than the melting point of solder, the material of inflection point forming portion 7 preferably exhibits modulus of elasticity higher than substrate 2 at the melting point of solder.

When a resin material is used as the material of inflection point forming portion 7, a filler can also be contained. In this event, the filler preferably exhibits the highest possible coefficient of thermal expansion. For example, silica, alumina, Cu, which are materials generally used as fillers, exhibit coefficients of thermal expansion 5×10⁻⁶/K, 7-8×10⁻⁶/K, 17×10⁻⁶/K, respectively. Accordingly, from a viewpoint of the coefficient of thermal expansion, a metal filler such as Cu is more preferable. Further, a silicon filler which exhibits an extremely large coefficient of thermal expansion, though with a low modulus of elasticity, advantageously increases the coefficient of thermal expansion of the material of inflection point forming portion 7 by combining with a resin which exhibits a high glass transition point (Tg) and a high rigidity, for example, such as silica hybrid. On the other hand, any of metal fillers such as silica, alumina, and Cu is preferable in order to improve the modulus of elasticity of the material of inflection point forming portion 7.

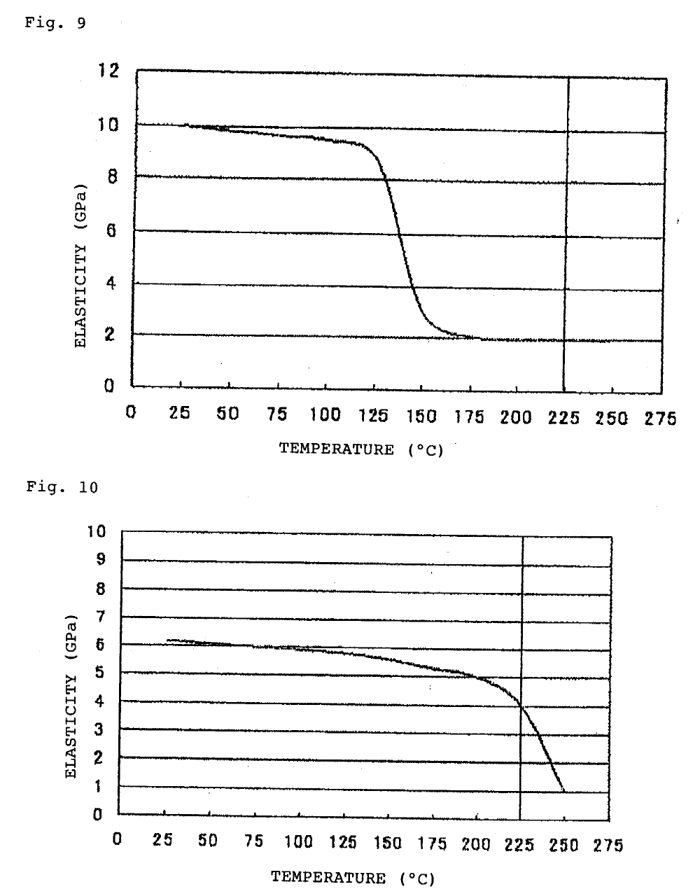

As described above, a variety of materials can be selected for inflection point forming portion 7. However, since the problem relative to the warping of substrate 2 occurs in the reflow step, the value in the solder reflow temperature range is important at the modulus of elasticity. FIG. 9 is a graph showing a temperature dependence of the modulus of elasticity for a glass cloth substrate of the material “FR-4” generally used as the material of substrate 2. This substrate exhibits a highly elasticity property of approximately 10 GPa at room temperature. However, in a range of 220° C. to 230° C. which includes the melting point of general Sn—Ag—Cu based solder as unleaded solder, the modulus of elasticity is approximately 2 GPa, about one fifth of that at the room temperature. Accordingly, in this event, the material of inflection point forming portion 7 may have a modulus of elasticity which exceeds 2 GPa in this temperature range. For example, a thermosetting amine-based epoxy resin which is a material having the elasticity property as shown in FIG. 10 can be applied. As shown in FIG. 10, this resin has the modulus of elasticity of 4 GPa at 225° C. above the elasticity 2 GPa of substrate 2, and is therefore preferable for the material of inflection point forming portion 7. Also, a resin material is known to exhibit the modulus of elasticity which suddenly becomes lower at the glass transition point temperature (Tg) or higher. Thus, when a resin material is used for the material of inflection point forming portion 7, the resin material preferably exhibits a high glass transition point temperature (Tg). More preferably, the glass transition point temperature (Tg) of the material of inflection point forming portion 7 exceeds the melting point of solder.

On the other hand, it is also possible to optimize the material of substrate 2 in order to increase the effect of inflection point forming portion 7. When using a material which exhibits a low modulus of elasticity in the solder reflow temperature region as the material of substrate 2, it is possible to apply the material of inflection point forming portion 7 which exhibits a low modulus of elasticity, so that it is preferable. In this way, the degree of freedom is increased in the selection of the material of inflection point forming portion 7. Likewise, the coefficient of thermal expansion of substrate 2 is preferably low, and is preferably closer to the coefficient of thermal expansion of semiconductor chip 1.

In almost materials of substrate 2, not limited to the aforementioned material “FR-4,” a sudden drop is seen in the modulus of elasticity above the glass transition point temperature (Tg). Moreover, the amount of drop, and a temperature at which the drop starts differ from one material to another. While the foregoing has shown the case of the material “FR-4,” a substrate material which has a resin impregnated in aramid unwoven fabric, for example, may be selected. For example, a substrate based on the aramid unwoven fabric exhibits a coefficient of thermal expansion lower than the material “FR-4,” approximately 10×10⁻⁶/K, and also exhibits a low modulus of elasticity in the solder reflow temperature range, resulting in an increased effect by inflection point forming portion 7. Also, in this substrate to which the aramid unwoven fabric is applied, since its coefficient of thermal expansion is low, the difference in the coefficient of thermal expansion with a metal material such as Cu is increased. For this reason, it is possible to apply an inorganic material such as a metal plate as the material of inflection point forming portion 7. In this event, it is important that substrate 2 is in close contact with inflection point forming portion 7 in the solder reflow temperature range.

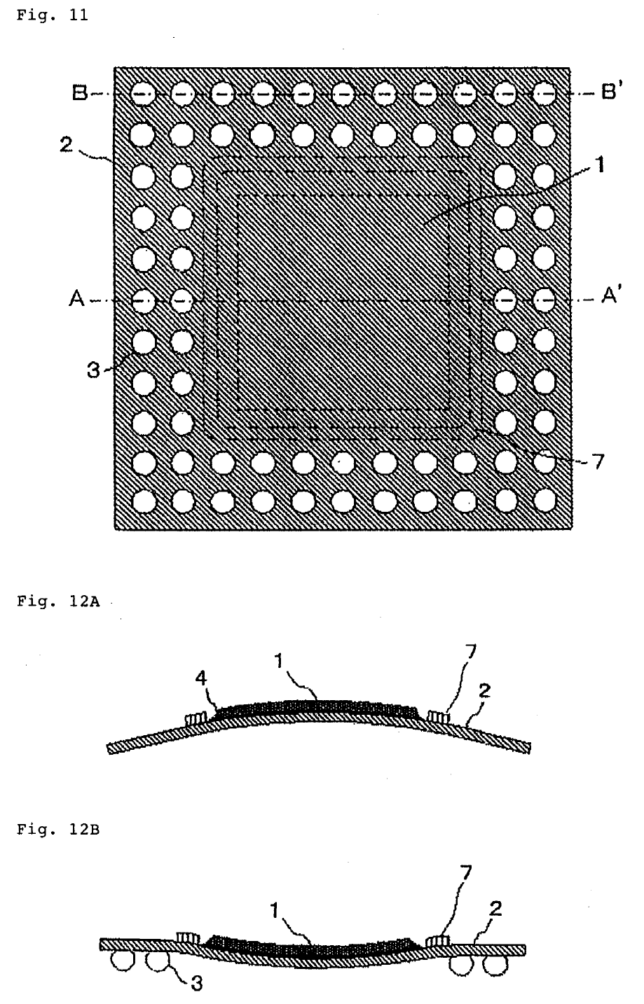

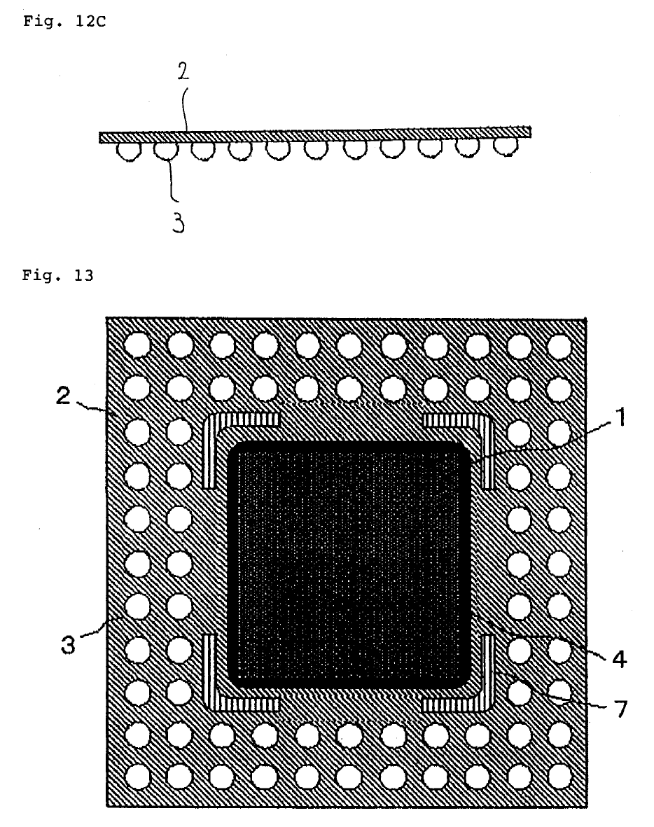

Next, a description will be given of a semiconductor package according to a second embodiment of the present invention. FIG. 11 is a plan view of the same, and FIGS. 12A-12C show cross-sectional views of the same. The first embodiment (FIG. 7) has shown an example of a semiconductor package which comprises semiconductor chip 1 and external terminals 3 that are arranged on the same surface of substrate 2. On the other hand, shown below is an example in which semiconductor chip 1 and external terminals 3 are arranged on different surfaces from each other.

FIG. 12A is a schematic cross-sectional view along A-A′ in FIG. 11, showing the state of the package at room temperature after the completion of the connection of semiconductor chip 1 with substrate 2, and after filling and curing of underfill resin 4 in a semiconductor package manufacturing process shown in FIG. 11. In this state, warping occurs in a direction in which the surface mounted with semiconductor chip 1 is convex, resulting from the difference in coefficient of thermal expansion between semiconductor chip 1 and substrate 2 due to a thermal load upon the flip-chip connection (see FIG. 12A). As is the case with FIG. 8A, the warping occurs where semiconductor chip 1 overlaps with substrate 2. As a result, substrate 1 draws a curve in a portion in which semiconductor chip 1 exists, whereas substrate 2 is linear in a portion in which semiconductor chip 1 does not exist. Also, in this event, the horizontality of the connection area can be ensured, as shown in FIG. 12B, by forming inflection point forming portion 7 on the surface on which semiconductor chip 1 is mounted. It is therefore possible to largely reduce defective connections.

In the first and second embodiments described above, semiconductor chip 1 and inflection point forming portion 7 are mounted on the same surface of substrate 2. However, inflection point forming portion 7 can also be formed on the surface opposite to the surface mounted with semiconductor chip 1. In this event, a material which exhibits a smaller coefficient of thermal expansion than substrate 2 can be used for the material of inflection point forming portion 7. In this way, it is possible to provide completely the same functions as those in each of the foregoing embodiments. Specifically, the horizontality of the connection area is ensured during the solder reflow, and defective connections can be largely reduced.

Next, a description will be given of a method of forming inflection point forming portion 7, and its shape. Inflection point forming portion 7 may be formed by any of the methods previously used for forming it on substrate 2 before semiconductor chip 1 is mounted and any of the methods for forming it after semiconductor chip 1 is mounted. For example, when a resin is used as the material of inflection point forming portion 7, formation by printing using a metal mask or a screen mask, or dispense formation can be applied.

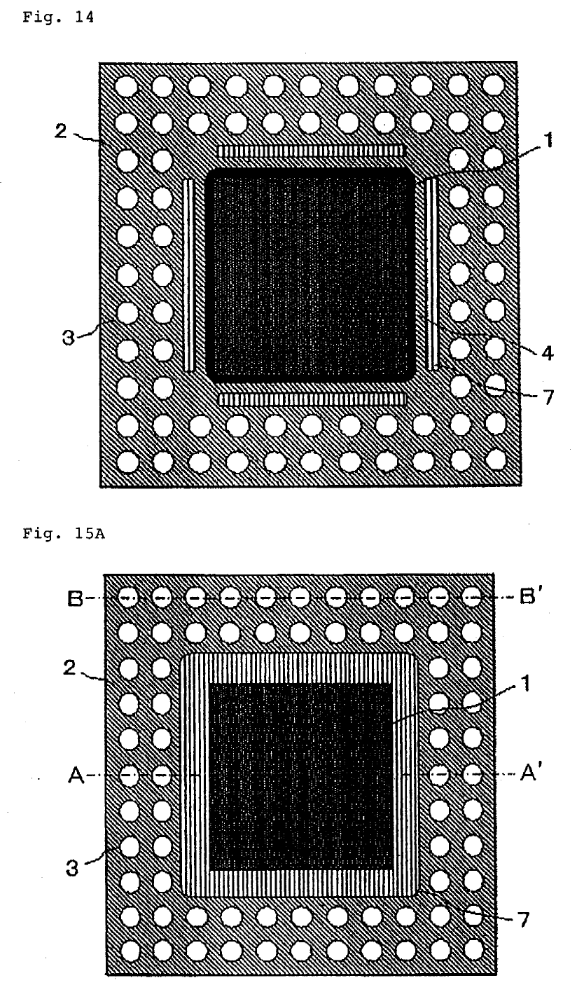

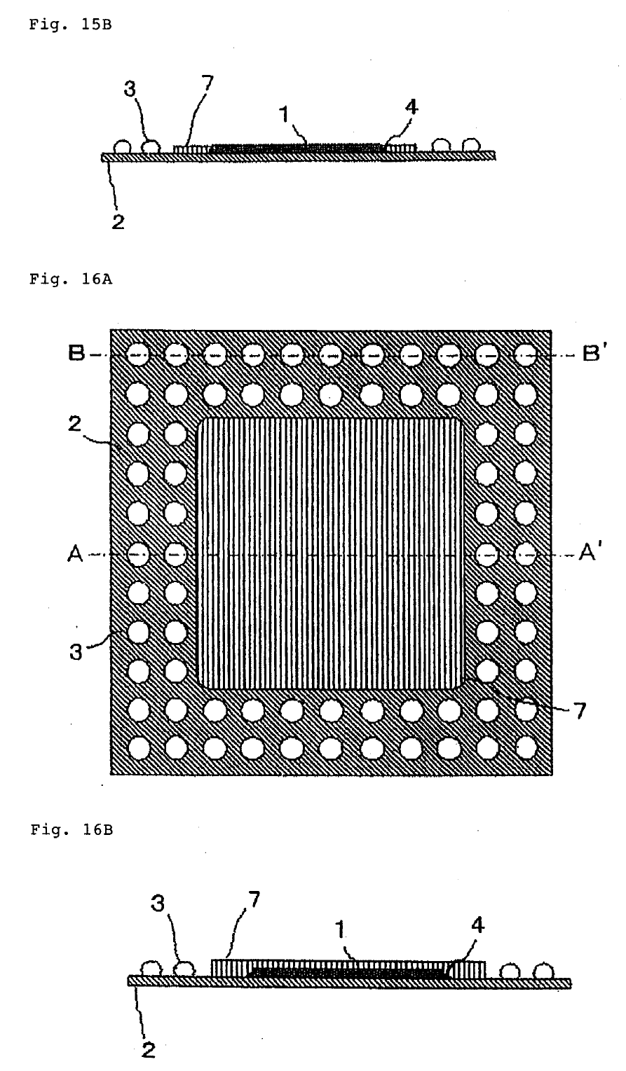

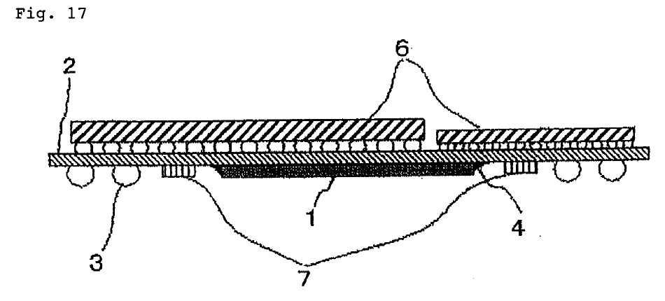

A variety of shapes can be used for inflection point forming portion 7. For example, when inflection point forming portion 7 is formed by printing using by a metal mask, advantages are that the cost merit is large, and flatness can be readily ensured for a printed resin surface. However, when inflection point forming portion 7 is continued around the overall periphery of semiconductor chip 1 by this formation by printing, the manufacturing of the metal mask is difficult. To accommodate such a situation, inflection point forming portion 7 may be formed only near four corners of semiconductor chip 1, as shown in FIG. 13. Alternatively, it may be shaped along the four sides of semiconductor chip 1, as shown in FIG. 14. In these shapes which have a break in part of inflection point forming portion 7, the inflection point can also formed in substrate 2, thus making it possible to correct the warping of substrate 2 to reduce defective solder connections in the connection area. Also, inflection point forming portion 7 may be in contact with semiconductor chip 1. For example, as shown in FIGS. 15A, 15B, the inner periphery of inflection point forming portion 7 may be in contact with the outer periphery of semiconductor chip 1. Further, as shown in FIGS. 16A, 16B, inflection point forming portion 7 may be not only arranged around the outer periphery of semiconductor chip 1 but also cover the top surface of semiconductor chip 1.

In inflection point forming portion 7, stress for correcting the warping of substrate 1 can be more readily generated because its volume is larger. Accordingly, a larger volume is advantageous in that a range of required physical properties is expanded in the properties required for the material of inflection point forming portion 7, for example, coefficient of thermal expansion, glass transition point, modulus of elasticity during heating, and the like, and the degree of freedom is increased in selecting the material of inflection point forming portion 7. However, when the area of the semiconductor package is to be increased in a planar direction, an area for mounting other parts will be reduced. Accordingly, it is necessary to set optimal inflection point forming portion 7 from the balance of them. In this event, an area in which inflection point forming portion 7 is arranged is preferably positioned as close as possible to semiconductor chip 1. In this event, since the inflection is possible closer to the root in regard to a portion outside of semiconductor chip 1 on substrate 2, it is possible to expand the range in which a desired flatness can be ensured for external terminals 3.

It is also possible to increase the stress for correcting the warping of substrate 2 by increasing the thickness of inflection point forming portion 7 in a thickness direction of the semiconductor package. However, the height of inflection point forming portion 7 is preferably made lower than parts mounted on the same surface so as not to reduce the advantage of a reduction in thickness of the semiconductor package.

In the structure of a conventional semiconductor package which relies on a reinforcing material to restrain warping of a substrate, the reinforcing material occupies a very large area on the semiconductor package and has a very large volume. For this reason, it is difficult to mount a plurality of electronic parts in the mounting area to the semiconductor package. On the contrary, the present invention employs a correcting method which forms inflection points partially in substrate 2 as a warping preventing method, thereby making it possible to minimize the structure for correcting warping. Thus, for example, as shown in FIG. 13, the area occupied by inflection point forming portion 7 can be reduced to provide one entire surface of the semiconductor package as a mounting area for other parts. Consequently, it is possible to realize a highly dense semiconductor package which maintains a small size and a low profile.

In the embodiments described above, the substrate and another substrate are connected through bumps in the semiconductor package of the present invention. However, this connection method is not limited to solder bump. Even with the use of another connection method, for example, a connection method that uses a conductive adhesive, the present invention is effective when the warping of a substrate is problematic.

Also, in the semiconductor package of the present invention, the substrate is corrected for warping by forming the inflection point forming portion made of a material exhibiting a larger coefficient of thermal expansion than the substrate in a part of the surface on which the semiconductor chip is mounted, and subsequently performing a thermal step. Alternatively, the substrate is corrected for warping by forming the inflection point forming portion made of a material exhibiting a larger coefficient of thermal expansion than the substrate in a part of the surface opposite to the surface on which the semiconductor chip is mounted, and subsequently performing a thermal step. It is apparent that such a warping correcting method can be widely applied to other than the embodiments described in this specification in a substrate which suffers from warp resulting from a difference in coefficient of thermal expansion between a substrate and a part mounted thereon in order to correct its warping.

A small and low-profile semiconductor package can be realized by using the warping correcting method of the present invention. Then, using this semiconductor package and substrate, it is possible to reduce the size and thickness of an electronic device to provide attractive products at low prices.

Also, the semiconductor package of the present invention is preferable for a system in package (SiP) which comprises a plurality of chips mixedly mounted in a single package. FIG. 17 shows a cross-sectional view of an example of this system in package. Here, another semiconductor package 6 is mounted on the semiconductor package of the present invention which comprises semiconductor chip 1, substrate 2, external terminals 3, underfill resin 4, and inflection point forming portion 7 to build a new semiconductor package (system in package). Such a structure can be realized due to the characteristics of the substrate corrected for warping and a small dead area in the semiconductor package of the present invention. In this way, the present invention can be applied to all semiconductor packages, irrespective of the type of devices, for example, a semiconductor package which contains semiconductor chips such as a CPU, logics, memories, and the like. By mounting individual semiconductor chips in the semiconductor package in the structure of the present invention, it is possible to realize a small, low-profile, high-density, high-reliability, and low-cost semiconductor package, as compared with the conventional semiconductor package. Also, by applying such a semiconductor package of the present invention to electronic devices, it is possible to further reduce the size and thickness of portable devices such as a portable telephone, a digital skill camera, PDA (Personal Digital Assistant), notebook personal computer and the like, which are required to be increasingly reduced in size and thickness, to increase the added value of products.

Finally, a description is given of the result of implementing the semiconductor package of the present invention. In a semiconductor package of the structure shown in FIG. 13, substrate 2 made of the material “FR-4,” inflection point forming portion 7 made of thermosetting amine-based epoxy resin which exhibits the properties shown in FIG. 10, and external terminal 3 made of unleaded solder Sn-3.5Ag-0.5Cu were used. A solder reflow was performed at 250° C. when this semiconductor package was connected to another substrate. As a result, the yield rate of the connections was 100%. On the other hand, the same semiconductor package was manufactured as above except that inflection point forming portion 7 was not provided, and was connected to another substrate through solder reflow in the same manner as above, resulting in the yield rate of 23% for connections. From this, the validity of the present invention can be confirmed.

1-18. (canceled)

19. A semiconductor package comprising:
a substrate;
a semiconductor chip mounted on one surface of said substrate; and
an inflection point forming portion formed in a part of the surface of said substrate on which said semiconductor chip is mounted, and said inflection point forming portion being made of a material having a larger coefficient of thermal expansion than said substrate.

20. The semiconductor package according to claim 19, wherein said inflection point forming portion is formed around the outer periphery of said semiconductor chip on said substrate.

21. The semiconductor package according to claim 20, wherein said inflection point forming portion includes a break in a part thereof.

22. The semiconductor package according to claim 19, wherein said semiconductor package is connected to another substrate using solder, and the material of said inflection point forming portion exhibits a modulus of elasticity higher than a modulus of elasticity of said substrate at the melting point of the solder.

23. The semiconductor package according to claim 19, wherein the material of said inflection point forming portion is made of a resin material.

24. The semiconductor package according to claim 19, wherein the material of said inflection point forming portion is made of an inorganic material.

25. A semiconductor package comprising:
a substrate;
a semiconductor chip mounted on one surface of said substrate; and
an inflection point forming portion formed in a part of a surface of said substrate opposite to the surface on which said semiconductor chip is mounted, and said inflection point forming portion being made of a material having a smaller coefficient of thermal expansion than said substrate.

26. The semiconductor package according to claim 25, wherein said inflection point forming portion is formed around the outer periphery of said semiconductor chip on said substrate.

27. The semiconductor package according to claim 26, wherein said inflection point forming portion includes a break in a part thereof.

28. The semiconductor package according to claim 25, wherein said semiconductor package is connected to another substrate using solder, and the material of said inflection point forming portion exhibits a modulus of elasticity higher than a modulus of elasticity of said substrate at the melting point of the solder.

29. The semiconductor package according to claim 25, wherein the material of said inflection point forming portion is made of a resin material.

30. The semiconductor package according to claim 25, wherein the material of said inflection point forming portion is made of an inorganic material.

31. A substrate for mounting a semiconductor chip thereon, comprising:
an inflection point forming portion formed in a part of a surface of said substrate on which said semiconductor chip is mounted, and said inflection point forming portion being made of a material having a larger coefficient of thermal expansion than said substrate.

32. The substrate according to claim 31, wherein said inflection point forming portion is formed around the outer periphery of said semiconductor chip on said substrate.

33. The substrate according to claim 32, wherein said inflection point forming portion includes a break in a part thereof.

34. The substrate according to claim 31, wherein said substrate is connected to another substrate using solder, and the material of said inflection point forming portion exhibits a modulus of elasticity higher than a modulus of elasticity of said substrate at the melting point of the solder.

35. The substrate according to claims 31, wherein the material of said inflection point forming portion is made of a resin material.

36. The substrate according to claims 31, wherein the material of said inflection point forming portion is made of an inorganic material.

37. A substrate for mounting a semiconductor chip thereon, comprising:
an inflection point forming portion formed in a part of a surface of said substrate opposite to a surface on which said semiconductor chip is mounted, and said inflection point forming portion being made of a material having a smaller coefficient of thermal expansion than said substrate.

38. The substrate according to claim 37, wherein said inflection point forming portion is formed around the outer periphery of said semiconductor chip on said substrate.

39. The substrate according to claim 38, wherein said inflection point forming portion includes a break in a part thereof.

40. The substrate according to claim 37, wherein said substrate is connected to another substrate using solder, and the material of said inflection point forming portion exhibits a modulus of elasticity higher than a modulus of elasticity of said substrate at the melting point of the solder.

41. The substrate according to claim 37, wherein the material of said inflection point forming portion is made of a resin material.

42. The substrate according to claim 37, wherein the material of said inflection point forming portion is made of an inorganic material.

43. An electronic device comprising the semiconductor package according to claim 19.

44. An electronic device comprising the semiconductor package according to claim 25.

45. An electronic device comprising the substrate according to claim 31.

46. An electronic device comprising the substrate according to claim 37.

47. A method for correcting warping in a semiconductor package which has a semiconductor chip mounted on one surface of a substrate, comprising:
forming an inflection point forming portion made of a material exhibiting a larger coefficient of thermal expansion than said substrate in a part of the surface on which said semiconductor chip is mounted; and
performing a thermal step.

48. A method for correcting warping in a semiconductor package which has a semiconductor chip mounted on one surface of a substrate, comprising:
forming an inflection point forming portion made of a material exhibiting a smaller coefficient of thermal expansion than said substrate in a part of the surface opposite to the surface on which said semiconductor chip is mounted; and
performing a thermal step.
